(19) United States
(12) Patent Application Publication
(10) Pub. No.: US 2004/0138769 A1
(43) Pub. Date: Jul. 15, 2004

(54) Digital amplifier and method for adjusting gain of same

(76) Inventor: Masaichi Akiho, Iwaki-city (JP)

Correspondence Address: BRINKS HOFER GILSON & LIONE, POST OFFICE BOX 10395, CHICAGO, IL, 60610, US

(21) Appl. No.: 10/706,609

(22) Filed: Nov. 12, 2003

(30) Foreign Application Priority Data
Dec. 27, 2002 (JP) 2002-380293

(51) Int. Cl. G06F 17/00; H03G 3/00

(52) U.S. Cl. 700/94; 381/104

(57) ABSTRACT

A digital amplifier for amplifying an input digital signal includes a sound-volume adjusting section for controlling the volume of the digital signal and a gain adjusting section for performing gain adjustment by applying compression characteristics to the digital signal subjected to volume control by the sound-volume adjusting section. Furthermore, the gain adjusting section performs calculation based on an expression y=a{1−1(1−[x])ⁿ} in order to apply compression characteristics to the input digital signal x, which is converted to the output signal y.

### BACKGROUND

1. Field of the Invention

The present invention relates to a digital amplifier for amplifying an input digital signal and to a method for adjusting the gain of a digital amplifier.

2. Description of the Related Art

Digital amplifiers are currently gaining increased attention. In fact, a growing number of music sources are being digitized and more cars are employing vehicle-mounted LANs for connecting various devices via a local area network, particularly in luxury cars.

In addition, digital signal processing (DSP) technology has become so advanced as to promote its application to high-efficiency audio pulse-width modulation (PWM) amplifiers (class D amplifiers) for achieving high sound quality. This technology, as compared with conventional analog PWM technology which is based on comparator outputs with respect to a triangular wave, is now widespread in digital amplifiers.

A conventional digital amplifier will now be described with reference to FIG. 4. A digital amplifier 1 includes an analog input section 2, an analog-to-digital (abbreviated to AD, A/D, or A-D in some cases) converter 3, a digital input section 4, a DSP audio controller 5, a digital volume controller 6, a PCM-to-PWM converter 7, and a class D amplifier 8. A speaker is denoted by reference numeral 9.

The digital amplifier 1 amplifies an input signal through pulse-width modulation and outputs the signal as an output voltage. The analog input section 2 receives an audio input signal as an analog signal. The analog-to-digital converter 3 performs analog-to-digital conversion of the audio input signal to a digital signal output represented by a predetermined number of bits (16 bits, for example). The digital input section 4 receives an audio input signal as a digital signal.

The DSP audio controller 5 performs various types of audio control on the input digital signal. The digital volume controller 6 controls the sound volume of the digital signal sent from the DSP audio controller 5. Upon receiving the n-bit digital data, the PCM-to-PWM converter 7 generates a pulse signal with a duty ratio according to the value of the received digital data. The class D amplifier 8 amplifies the signal through high-speed switching.

Technology similar to the conventional technology described above is disclosed in Japanese Unexamined Patent Application Publication No. 2002-151974, which will be described below. FIG. 5 illustrates a digital amplifier described in Japanese Unexamined Patent Application Publication No. 2002-151974. Referring to FIG. 5, a conventional digital amplifier 30 includes an analog-to-digital converter 32 for detecting a supply voltage E or −E; an analog-to-digital converter 34 for detecting an output voltage Vo; an analog-to-digital converter 40 for receiving an input voltage Vi; and a DSP 36 for calculating a pulse width based on the output voltage Vo detected by the analog-to-digital converter 34, the supply voltage E or −E detected by the analog-to-digital converter 32, and the input voltage Vi detected by the analog-to-digital converter 40.

The DSP 36 calculates a load resistance R based on the output voltage Vo and calculates a pulse width based on the load resistance R, the supply voltage E or −E, and the input voltage Vi. This approach allows the pulse width to be corrected according to a change in the supply voltages, thereby suppressing fluctuation of the output voltage Vo arising from fluctuating supply voltages. The analog-to-digital converter 40 receives through an input terminal 38 the input voltage Vi, which includes an analog audio signal, converts the analog signal to a digital signal, and provides the digital signal to the DSP 36.

The DSP 36 determines the pulse width of the digital signal based on a predetermined mathematical expression and provides to a PWM-generating logic circuit 42 an n-bit parallel digital signal representative of the pulse width, where n is a predetermined number. The PWM-generating logic circuit 42 generates a pulse having the determined pulse width, and drives power MOSFET components 461 through gate drivers 441 and 442, respectively, corresponding to the positive and negative polarities. In the digital amplifier 30 structured as described above, the output voltage Vo at an output terminal 48 rises or drops according to the pulse width and thus a speaker (not shown in FIG. 5) connected to the output terminal 48 is energized by the output voltage Vo. This mechanism greatly reduces the distortion of the output signal.

The digital amplifier disclosed in Japanese Unexamined Patent Application Publication No. 2002-151974 is based on DSP technology and is controlled so as not to cause the maximum signal value in a signal processing system to exceed the maximum value allowed in the DSP. Thus, this digital amplifier guarantees an extremely low level of distortion at all times, achieving the maximum possible signal-to-noise ratio. As a result, in principle, a substantially distortion-free output having an amplitude substantially equal to that of the supply voltage in the amplifier can be obtained.

Japanese Unexamined Patent Application Publication No. 5-344078 assigned to the assignee of the present invention also proposes a variable digital processor. In such a variable digital processor, an input audio signal is given compression characteristics that can be changed according to the value of the variable exponent n in the mathematical expression used for digital signal processing. A variable digital processor with this function permits an audio signal to have such compression characteristics as available with an analog system.

In the conventional digital amplifier, a supply voltage in the amplifier completely matches the output power. This means that doubling the supply voltage causes the gain of the digital amplifier also to be doubled. The gain of the digital amplifier is therefore dependent on the supply voltage in the amplifying section of the output stage. Even in such a digital amplifier, a user may be provided with a variable gain function, which may be achieved as follows. While an input signal is multiplied by a coefficient smaller than 1 through DSP to decrease the gain of the digital amplifier, the user can set the gain, which causes the coefficient to be changed accordingly. This solution, however, degrades the signal-to-noise ratio of a playback signal unless the user selects the maximum gain setting, possibly failing to provide the maximum performance of the audio system.

Another advantage of analog circuits is their feature of gradual saturation, which occurs if the level of signal being processed is extremely high, thus preventing excessive distortion of the signal. In contrast, digital processing suffers from excessive distortion of the signal waveform as a result of the signal waveform being clipped when the signal level overshoots, that is, exceeds the maximum number represented by the quantizing bit number.

### SUMMARY OF THE INVENTION

Accordingly, an object of the present invention is to provide a digital amplifier capable of soft clipping and a method for adjusting the gain of such a digital amplifier in order to overcome the problems described above. Another object of the present invention is to provide a digital amplifier capable of varying its gain and a method for adjusting the gain of such a digital amplifier while still maintaining the signal-to-noise ratio of a playback signal.

According to an aspect of the present invention, the above objects are achieved using a digital amplifier for amplifying an input digital signal, i.e., a digital amplifier which includes a volume adjusting section for controlling the volume of the digital signal and a gain adjusting section for performing gain adjustment by applying compression characteristics to the volume-controlled digital signal.

This enables soft clipping where an output is clipped gradually. Thus, the digital amplifier is capable of exhibiting a behavior like an analog amplifier receiving an extremely high input signal, allowing soft clipping to be controlled at the time of a high output.

The gain adjusting section may apply the compression characteristics to the input digital signal, which is converted to an output signal, through a calculation based on an expression y=a{1−1(1−[x])ⁿ}, where x is the input digital signal, y is the output signal, [x] is the absolute value of x, n is an exponent representing the compression characteristics, and a is 1 for x≧0 or −1 for x<0.

This enables gain adjustment such that the output is clipped gradually. Thus, the digital amplifier is capable of exhibiting a behavior like an analog amplifier receiving an extremely high input signal, allowing soft clipping to be controlled at the time of a high output.

The compression characteristics may be variable by changing the exponent n. This allows the gain of the digital amplifier dependent on a supply voltage to be varied. Thus, the gain can be adjusted without degrading the signal-to-noise ratio of a playback signal.

The exponent n may be variable according to the operation of a gain adjusting function. Thus, the user is allowed to change the exponent n at his or her discretion, for example, by using the gain adjusting function. For this reason, the user is allowed to change the gain by the gain adjusting section at his or her discretion.

The digital amplifier may further include a memory for storing an input-output conversion table corresponding to the input-output relationship defined by an expression y=a{1−1(1−[x])ⁿ}, where x is the input digital signal. In this case, the gain adjusting section may perform gain adjustment by referring to the input-output conversion table stored in the memory.

This approach allows intermediate gain values not obtained based on the expression, such as 1 [dB] and 5 [dB], to be used for gain adjustment, ensuring gain adjustment of the digital amplifier based on an optimal value without degrading the signal-to-noise ratio of a playback signal.

The gain adjusting section may be a digital signal processor (DSP).

According to another aspect of the present invention, the above objects are achieved by a method for adjusting the gain of a digital amplifier for amplifying an input digital signal, including a volume adjusting step of controlling the volume of the digital signal and a gain adjusting step of adjusting the gain by applying compression characteristics to the volume-controlled digital signal.

This approach allows soft clipping to be controlled at the time of a high output by performing gain adjustment such that an output signal is clipped gradually in the gain adjusting step.

In the gain adjusting step, the compression characteristics may be applied to the input digital signal, which is converted to an output signal, through a calculation based on an expression y=a{1−1(1−[x])ⁿ}, where x is the input digital signal, y is the output signal, [x] is the absolute value of x, n is an exponent representing the compression characteristics, and a is 1 for x≧0 or −1 for x<0.

This approach enables gain adjustment such that the output signal is clipped gradually, thus allowing soft clipping to be controlled at the time of a high output.

The compression characteristics may be variable by changing the exponent n. This allows the gain of the digital amplifier dependent on a supply voltage to be varied. Thus, the gain of the digital amplifier can be adjusted without degrading the signal-to-noise ratio of a playback signal.

The exponent n may be variable according to the operation of a gain adjusting function. Thus, the user is allowed to change the exponent n at his or her discretion, for example, by using the gain adjusting function. For this reason, the user is allowed to change the gain in the gain adjusting step at his or her discretion without degrading the signal-to-noise ratio of a playback signal.

In the gain adjusting step, gain adjustment may be performed by referring to a memory storing an input-output conversion table corresponding to the input-output relationship defined by an expression y=a{1−1(1−[x])ⁿ}, where x is the input digital signal.

This approach allows intermediate gain values, such as 1 [dB] and 5 [dB], to be used for gain adjustment, ensuring gain adjustment of the digital amplifier based on an optimal conversion value.

### BRIEF DESCRIPTION OF THE DRAWINGS

FIG. 1 illustrates a digital power amplifier according to an embodiment of the present invention;

FIG. 2 is a block diagram of a soft-clipping gain adjusting section;

FIG. 3 includes graphs representative of the input-output characteristics of a digital power amplifier according to an embodiment of the present invention, wherein the graphs are represented logarithmically;

FIG. 4 illustrates a conventional digital amplifier; and

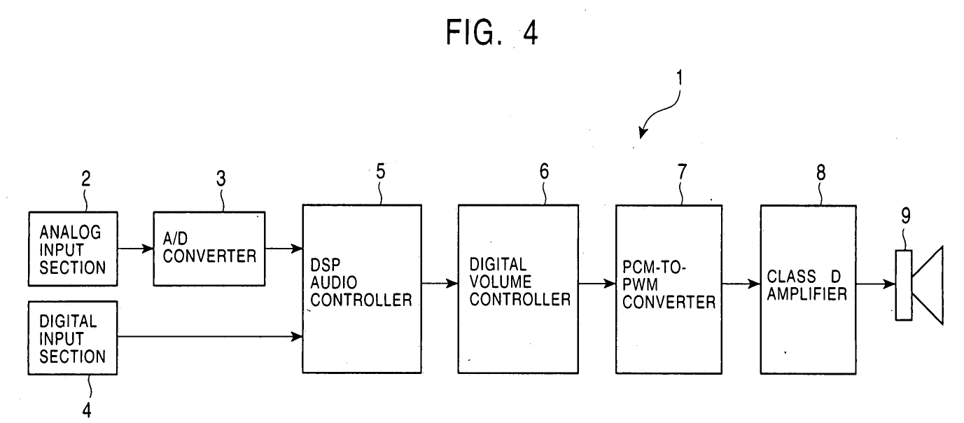

FIG. 5 illustrates a digital amplifier described in Japanese Unexamined Patent Application Publication No. 2002-151974.

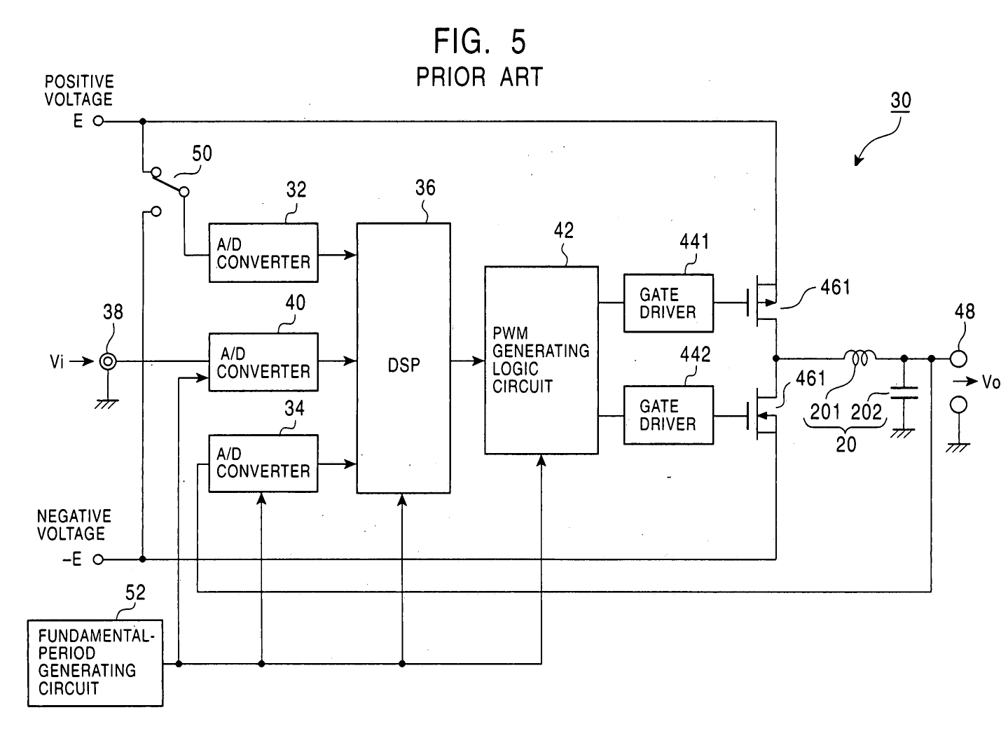

### DETAILED DESCRIPTION OF THE DRAWINGS AND THE PREFERRED EMBODIMENTS

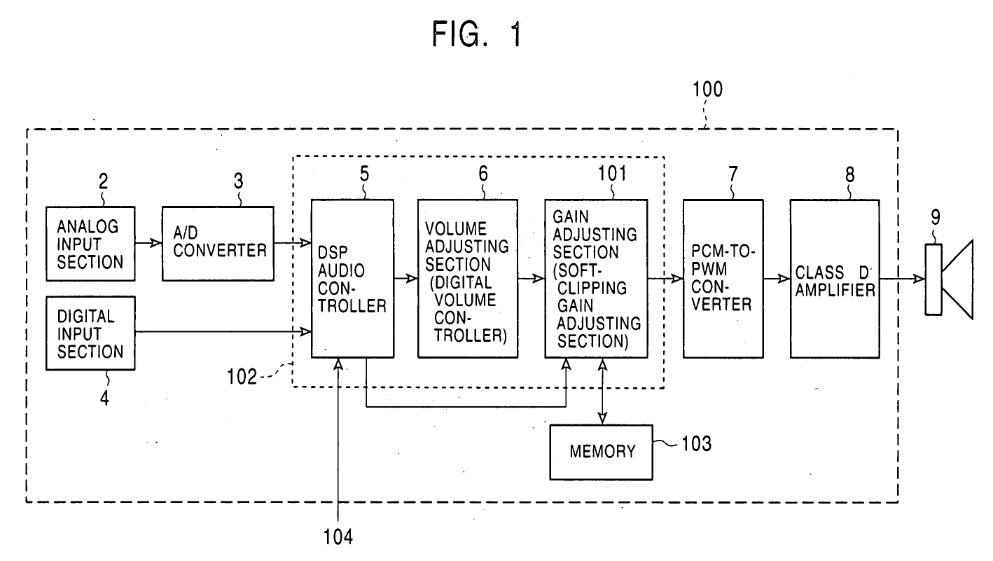

An embodiment of the present invention will now be described with reference to the attached drawings. A digital amplifier according to an embodiment of the present invention includes a digital class D amplifier to achieve signal distortion similar to that possible with an analog signal. FIG. 1 illustrates a digital power amplifier 100 according to an embodiment of the present invention. The digital power amplifier 100 amplifies an input signal through pulse-width modulation and provides the signal as an output voltage.

Referring to FIG. 1, the digital power amplifier 100 includes an analog input section 2, an analog-to-digital converter 3, a digital input section 4, a DSP audio controller 5, a digital volume controller 6, a soft-clipping gain adjusting section 101, a PCM-to-PWM converter 7, a class D amplifier 8, and a memory 103. FIG. 1 also shows a speaker 9, a DSP 102, and an operating section 104.

The analog input section 2 receives an audio input signal as an analog signal. The analog-to-digital converter 3 performs analog-to-digital conversion of the audio input signal to a digital signal output represented by a predetermined number of bits (16 bits, for example). In more detail, the analog audio signal input received the analog input section 2 is converted to a digital audio signal by the analog-to-digital converter 3 and is then passed to the DSP audio controller 5.

The digital input section 4 receives an audio input signal as a digital signal. In more detail, the digital audio signal input from the digital input section 4 is provided directly to the DSP audio controller 5. The DSP audio controller 5 performs various types of audio control on the input digital signal. The DSP audio controller can also receive a control signal from a user who operates the operating section 104. An audio control signal from the user may be for balance control, fader control, sound-quality control, graphic equalizer control, or acoustic-field control. The digital volume controller 6 is a sound-volume adjusting section that performs sound volume control on the digital signal from the DSP audio controller 5.

The soft-clipping gain adjusting section 101 performs gain adjustment of the digital signal subjected to volume control by the digital volume controller 6, and further performs soft clipping control of the digital signal if the signal has a high output level.

This soft-clipping gain adjusting section 101 also performs calculations based on the expression

y=a{1−1(1−[x])ⁿ} (1)

where x is the input signal to which compression characteristics are applied to form the output signal y. In expression (1), [x] represents the absolute value of the input signal x, n represents an exponent for specifying the compression characteristics, and a represents a coefficient that is 1 for x≧0 or −1 for x<0. Soft clipping is performed in this manner when a high output signal is to be controlled.

Another feature of the soft clipping described above is that the compression characteristics can be changed by varying the exponent n. In other words, this soft clipping function allows the gain of the digital amplifier dependent on a supply voltage to be varied. Furthermore, the gain can be adjusted without degrading the signal-to-noise ratio of a playback signal. The exponent n may be varied according to the user's operation of a gain adjustment function. The DSP audio controller 5, the digital volume controller 6, and the soft-clipping gain adjusting section 101 can be implemented using a DSP.

Upon receiving the n-bit digital data, the PCM-to-PWM converter 7 generates a pulse signal with a duty ratio according to the value of the received digital data. The class D amplifier 8 amplifies the signal through high-speed switching.

The memory 103 stores an input-output conversion table representative of the input-output relationship defined by the expression y=a{1−1(1−[x])ⁿ}, where x is the input signal. The soft-clipping gain adjusting section 101 may be allowed to refer to the input-output conversion table stored in the memory 103 to perform gain adjustment. A memory device such as a ROM (read-only memory) can be used for this memory 103.

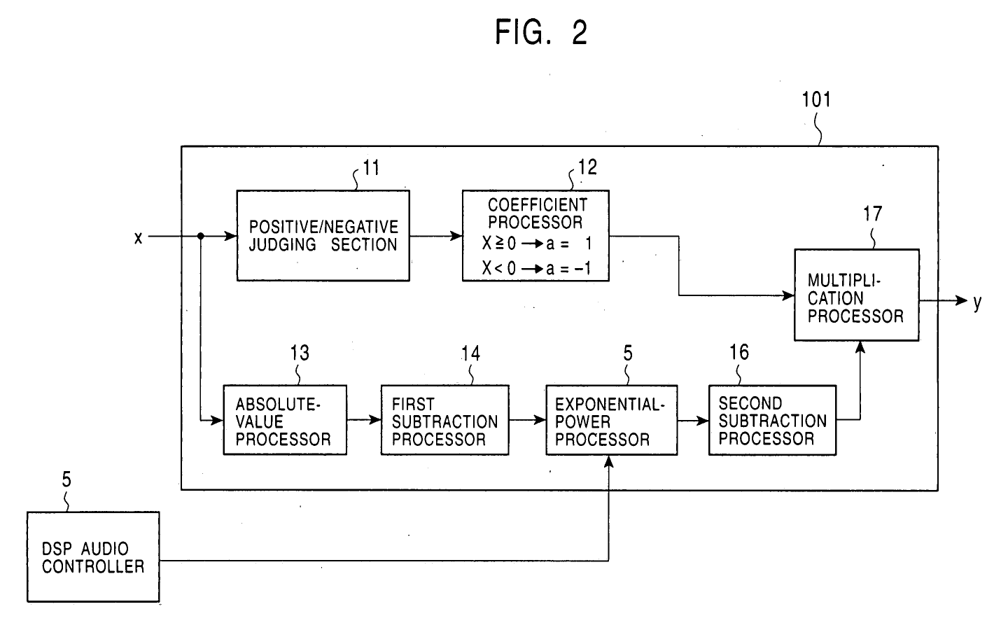

The soft-clipping gain adjusting section 101 will now be described in more detail. FIG. 2 is a block diagram of the soft-clipping gain adjusting section 101. Referring to FIG. 2, the soft-clipping gain adjusting section 101 includes a positive/negative judging section 11, a coefficient processor 12, an absolute-value processor 13, a first subtraction processor 14, an exponential-power processor 15, a second subtraction processor 16, and a multiplication processor 17.

The soft-clipping gain adjusting section 101 performs calculation of y=a{1−1(1−[x])ⁿ} to apply compression characteristics to the input signal x to form the output signal y. In the expression above, values enclosed by brackets [ ] represent absolute values. Hence, [x] represents the absolute value of the signal x. The exponent n specifies the compression characteristics, and is variably set according to the target compression characteristics. The coefficient a is set according to the polarity of the input signal x, that is, to 1 for x≧0 or −1 for x<0.

In more detail, the positive/negative judging section 11 judges whether the input signal x is positive or negative. The positive/negative judging section 11 judges, for example, whether x≧0 and outputs the result to the coefficient processor 12. The coefficient processor 12 sets the value of the coefficient a according to the judgment by the positive/negative judging section 11. In more detail, if the input signal x is equal to or higher than 0, as described above, the coefficient processor 12 sets the value of the coefficient a to 1. On the other hand, the coefficient processor 12 set the value of the coefficient a to −1 if the input signal x is smaller than 0. The value of this coefficient a is passed to the multiplication processor 17 as information about the polarity of the output signal

The absolute-value processor 13 obtains the absolute value [x] of the amplitude (level) of the input signal x and outputs the obtained absolute value [x] to the first subtraction processor 14. The first subtraction processor 14 subtracts the received absolute value [x] from a constant 1, thus calculating the complement of [x] as normalized with the maximum amplitude of the input signal x set to 1. Based on the complement <1−[x]>, the attenuation of the input signal x is represented logarithmically with respect to the level of the input signal x. In more detail, the complement <1−[x]> undergoes exponential-power processing based on the value of the exponent n that has been set by the exponential-power processor 15, thus determining the compression characteristics according to the signal level.

Specifically, the exponential-power processor 15 performs exponential-power processing of <1−[x]>x<1−[x]>=<1−[x]>² if the exponent n is 2, <1−[x]>x<1−[x]>x<1−[x]>=<1−[x]>³ if the exponent n is 3, and <1−[x]>x<1−[x]>x<1−[x]>x<1−[x]>=<1−[x]>⁴ if the exponent n is 4.

In other words, the attenuation to be applied to the input signal x is determined according to the signal level through exponential-power processing by the exponential-power processor 15. It should be noted that the compression scheme described above features inverse compression characteristics where the higher the signal level, the less the attenuation, and the lower the signal level, the more the attenuation.

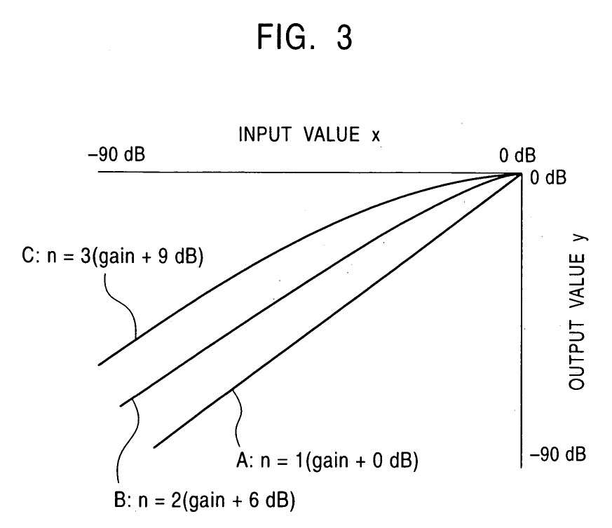

The second subtraction processor 16 subtracts the attenuation obtained as described above from the normalized value 1, thus determining the attenuation to be actually applied to the input signal x. This subtraction determines compression characteristics where the higher the signal level, the more the attenuation, and the lower the signal level, the less the attenuation, as shown in FIG. 3. In this manner, a signal which is variable according to the level of the input signal x is obtained based on the expression 1−<1−[x]>ⁿ. Subsequently, the signal output from the second subtraction processor 16 is passed to the multiplication processor 17, multiplied by the above coefficient a, and converted to an output signal y having the polarity according to the polarity of the input signal x.

According to the soft-clipping gain adjusting section 101 that performs the signal processing described above, compression characteristics according to the exponent n can be applied to the input signal x by simple processing, i.e., without division processing.

In short, according to the digital amplifier of the embodiment, the soft-clipping gain adjusting section 101 applies compression characteristics to the input signal x to form the output signal y according to the calculation result based on the expression y=a{1−(1−[x])ⁿ}, thereby allowing the gain to be adjusted as if the output signal y were clipped gradually. Thus, this digital amplifier is capable of exhibiting a behavior like an analog amplifier receiving an extremely high input signal. Furthermore, a high output can be controlled through soft clipping.

The exponent n in the above expression may be changed by the user who operates the operating section 104, which may be provided with a gain adjusting function. In this case, the user is allowed to change the exponent n at his or her discretion by using the gain adjusting function. The user can thus adjust the gain through the gain adjusting section.

The logarithmically represented input-output characteristics of the digital amplifier according to the embodiment of the present invention will be described with reference to FIGS. 1 to 3. FIG. 3 includes graphs representative of the input-output characteristics of the digital power amplifier according to the embodiment of the present invention, wherein the graphs are logarithmic graphs. Referring to FIG. 3, the horizontal axis represents an input value x (input signal), and the vertical axis represents an output value y (output signal). In FIG. 3, curves A, B, and C represent the input-output characteristics of the digital power amplifier where exponent n=1, n=2, and n=3, respectively.

Referring again to FIG. 1, the soft-clipping gain adjusting section 101 is disposed after the digital volume controller 6 in the digital amplifier 100. In this structure, when the user operates the operating section 104, the information set by the user is transferred to the soft-clipping gain adjusting section 101 through the DSP audio controller 5, thus allowing the user to change the exponent n of the mathematical expression described above as n=0, 1, 2 and so on.

The calculation procedures are described below with reference to FIG. 2, assuming that the input signal x=0.9. When the exponent n=1, the first subtraction processor 14 calculates <1−[x]>=1−0.9=0.1, the exponential-power processor 15 calculates <1−[x]>¹=0.1, the second subtraction processor 16 calculates {1−1(1−[x])¹}=0.9, and finally the multiplication processor 17 calculates y=a{1−1(1−[x])¹}=0.9.

In the same manner, when the exponent n=2, the first subtraction processor 14 calculates <1−[x]>=1−0.9=0.1, the exponential-power processor 15 calculates <1−[x]>²⁼0.01, the second subtraction processor 16 calculates {1−1(1−[x])²}=0.99, and finally the multiplication processor 17 calculates y=a{1−1(1−[x])²}=0.99.

When the exponent n=3, the first subtraction processor 14 calculates <1−[x]>=1−0.9=0.1, the exponential-power processor 15 calculates <1−[x]>³=0.001, the second subtraction processor 16 calculates {1−1(1−[x])³}=0.999, and finally the multiplication processor 17 calculates y=a{1−1(1−[x])³}=0.999.

Thus, the input-output characteristics exhibit a gradual change as to converge to 1, as shown by the graphs A, B, and C in FIG. 3 where gain G is +6 dB for n=2 and +9 dB for n=3. In this manner, soft clipping is achieved.

If the gain of the digital amplifier 100 as determined by the supply voltage is G [dB], the gain G can be varied as G [dB] for n=1, G+6 [dB] for n=2, G+9 [dB] for n=3, G+12 [dB] for n=4 and so on. The output signal undergoes soft clipping for each setting of n. Thus, this digital amplifier is capable of exhibiting a behavior like an analog amplifier receiving an extremely high input signal.

The soft-clipping gain adjusting section 101 disposed after the digital volume controller 6 in the digital amplifier 100 and the soft-clipping gain adjusting section 101 that performs processing based on the above expression (1) allow the digital amplifier 100 to saturate smoothly in the same manner as an analog amplifier. This achieves a behavior like an analog compressor.

The digital amplifier according to the foregoing embodiment does not perform processing: that is, it produces a linear signal even when it receives a high-level input signal as long as the volume is set low. On the other hand, the same digital amplifier activates soft clipping as described above when the volume is increased to such a level that the output signal almost reaches saturation. This mechanism allows the digital amplifier to behave like an analog amplifier.

Furthermore, the digital amplifier 100 according to the embodiment allows the gain G thereof to be changed freely by changing the exponent n, unlike the conventional digital amplifier 1 whose gain is dependent on the supply voltage. In an audio system composed of digital components only, a soft-clipping gain adjusting section installed downstream of a volume control section enables soft clipping as described above. In a conventional amplifier, a DSP is used to perform volume control of a signal through a digital-to-analog converter before the signal enters the volume control section to maintain its maximum performance for signal matching. In contrast, the digital amplifier 100 according to the embodiment is implemented so that soft clipping is applied to a digital signal that has undergone volume control, thus achieving the soft clipping function as described above.

The digital amplifier according to the embodiment may be implemented such that the exponent n can be changed by the provision of a gain adjusting function. In other words, the digital amplifier may be implemented such that gain adjustment is linked with a change in the exponent n. The digital amplifier may also be implemented such that the exponent n is variable so as to allow the user to select the value of the exponent n. Users wishing distortion-free sound over the entire range would set the exponent n to 1, whereas users wishing powerful sound despite distortion at higher volumes would set the exponent n to 2 or 3. According to the foregoing embodiment, the exponent n in expression (1) is variable so as to change in response to the user's operation of the operating section 104. The exponent n, however, may be fixed to a particular value.

The embodiment of the present invention has been described. The present invention is not limited to the foregoing embodiment, but various modifications are conceivable within the scope of the present invention.

1. A digital amplifier for amplifying an input digital signal, comprising:
a volume a volume adjusting section for controlling the volume of the digital signal; and
a gain adjusting section for performing gain adjustment by applying compression characteristics to the volume-controlled digital signal.

2. The digital amplifier according to claim 1, wherein the gain adjusting section applies the compression characteristics to the input digital signal, which is converted to an output signal, through a calculation based on an expression y=a{1−1(1−[x])ⁿ}, where x is the input digital signal, y is the output signal, [x] is the absolute value of x, n is an exponent representing the compression characteristics, and a is 1 for x≧0 or −1 for x<0.

3. The digital amplifier according to claim 2, wherein the compression characteristics are variable by changing the exponent n.

4. The digital amplifier according to claim 3, wherein the exponent n is variable according to an operation of a gain adjusting function.

5. The digital amplifier according to claim 1, further comprising:
a memory for storing an input-output conversion table corresponding to the input-output relationship defined by an expression y=a {1−1(1−[x])ⁿ}, where x is the input digital signal, y is an output signal, [x] is the absolute value of x, n is an exponent representing the compression characteristics, and a is 1 for x≧0 or −1 for x<0, wherein the gain adjusting function performs gain adjustment by referring to the input-output conversion table.

6. The digital amplifier according to claim 1, wherein the gain adjusting section comprises a digital signal processor.

7. The digital amplifier according to claim 2, wherein the gain adjusting section comprises a digital signal processor.

8. The digital amplifier according to claim 5, wherein the gain adjusting section comprises a digital signal processor.

9. The digital amplifier according to claim 1, further comprising:
an analog input section for receiving an analog signal; and
an analog-to-digital converter for converting the analog signal to a digital signal and providing the digital signal to the volume adjusting section.

10. The digital amplifier according to claim 2, further comprising:
an analog input section for receiving an analog signal; and
an analog-to-digital converter for converting the analog signal to a digital signal and providing the digital signal to the volume adjusting section.

11. A method for adjusting the gain of a digital amplifier for amplifying an input digital signal, the method comprising:
controlling the volume of the digital signal; and
performing gain adjustment by applying compression characteristics to the volume-controlled digital signal.

12. The method according to claim 11, wherein the compression characteristics are applied to the input signal, which is converted to an output signal, through a calculation based on an expression y=a{1−1(1−[x])ⁿ}, where x is the input digital signal, y is the output signal, [x] is the absolute value of x, n is an exponent representing the compression characteristics, and a is 1 for x≧0 or −1 for x<0.

13. The method according to claim 12, wherein the compression characteristics are variable by changing the exponent n.

14. The method according to claim 13, wherein the exponent n is variable according to an operation of a gain adjusting function.

15. The method according to claim 11, wherein the gain adjustment is performed by referring to a memory storing an input-output conversion table corresponding to the input-output relationship defined by an expression y=a{1−1(1−[x])ⁿ}, where x is the input digital signal, y is an output signal, [x] is the absolute value of x, n is an exponent representing the compression characteristics, and a is 1 for x≧0 or −1 for x<0.
